(19) United States
(12) Patent Application Publication
(10) Pub. No.: US 2024/0112004 A1
(43) Pub. Date: Apr. 4, 2024

(54) METHOD AND APPARATUS WITH 3D IN-MEMORY COMPUTING

(71) Applicant: SAMSUNG ELECTRONICS CO., LTD., Suwon-si (KR)

(72) Inventors: Jangho AN, Suwon-si (KR); Seungchul JUNG, Suwon-si (KR); Soon-Wan KWON, Suwon-si (KR)

(73) Assignee: SAMSUNG ELECTRONICS CO., LTD., Suwon-si (KR)

(21) Appl. No.: 18/115,891

(22) Filed: Mar. 1, 2023

(30) Foreign Application Priority Data
Oct. 4, 2022 (KR) 10-2022-0126306

(51) Int. Cl. G06N 3/063; G06F 7/544; G06N 3/04; H10B 10/00

(52) U.S. Cl. CPC G06N 3/063; G06F 7/5443; G06N 3/04; H10B 10/12; H10B 10/18

(57) ABSTRACT

An apparatus including a memory layer including a plurality of front-end-of-line (FEOL) memory cells and a logic layer including plural arithmetic logic gates including back-end-of-line (BEOL) transistors, the plurality of BEOL transistors being vertically stacked on respective upper ends of the plurality of memory cells, wherein each of multiple transistors of the plurality of BEOL transistors operates as a multiplier and is configured to provide an operation result with respect to first values stored in corresponding memory cells of the plurality of memory cells.

### CROSS-REFERENCE TO RELATED APPLICATIONS

This application claims the benefit under 35 USC § 119(a) of Korean Patent Application No. 10-2022-0126306, filed on Oct. 4, 2022, in the Korean Intellectual Property Office, the entire disclosure of which is incorporated herein by reference for all purposes.

### BACKGROUND

### 1. Field

The following description relates to a method and apparatus with three-dimensional (3D) in-memory computing (IMC).

### 2. Description of Related Art

The utilization of deep neural networks (DNNs) is leading to an industrial revolution based on artificial intelligence (AI). One type of DNN is the convolutional neural network (CNN). The CNN is widely used in various application fields such as, for example, image and signal processing, object recognition, computer vision, and the like that mimic the human optic nerve. The CNN may be configured to perform a multiplication and accumulation (MAC) operation that repeats multiplication and addition using a considerably large number of matrices.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a memory layer including a plurality of front-end-of-line (FEOL) memory cells and a logic layer including plural arithmetic logic gates including back-end-of-line (BEOL) transistors, the plurality of BEOL transistors being vertically stacked on respective upper ends of the plurality of memory cells, wherein each of multiple transistors of the plurality of BEOL transistors operates as a multiplier and is configured to provide an operation result with respect to first values stored in corresponding memory cells of the plurality of memory cells.

The multiple transistors may be configured to share an input data line connected in a row direction in the logic layer through respective gate terminals of the multiple transistors and the multiplier operation results may be multiplier results between the first values and a second value applied through the input data line, and are output for each column of a memory array including multiple memory cells of the plurality of memory cells.

A total number of the multiple transistors may be equal to a total number of the plurality of memory cells and wherein a total number of the multiple memory cells may be equal to a total number of the plurality of memory cells.

The plural arithmetic logic gates may be vertically stacked to respectively correspond to the plurality of memory cells.

The plurality of BEOL transistors may each include a negatively doped metal-oxide semiconductor (n-MOS) transistor, a source terminal of the n-MOS transistor is grounded through a resistor, a gate terminal of the n-MOS transistor is connected to an input data line, a drain terminal of the n-MOS transistor is connected to a memory cell corresponding to an arithmetic logic gate of the plurality of memory cells, and the operation result may be output through an output node disposed between the source terminal of the n-MOS transistor and the resistor.

The plurality of BEOL transistors may each include a positively doped metal-oxide semiconductor (p-MOS) transistor, a gate terminal of the p-MOS transistor is connected to an input data line, a drain terminal of the p-MOS transistor is connected to a memory cell corresponding to an arithmetic logic gate of the plurality of memory cells, a source terminal of the p-MOS transistor is connected to a voltage source (VDD) through a resistor, and the operation result may be output through an output node disposed between the source terminal of the p-MOS transistor and the resistor.

The plurality of BEOL transistors may include any one or any combination of two or more of a thin film transistor (TFT), a ferroelectric field-effect transistor (FeFET), a two-dimensional (2D) field effect transistor (FET), and a polycrystalline silicon (poly-Si) channel FET.

The logic layer may include a plurality of logic layer memory cells, a unit cell may represent a collection of one memory cell of the plurality of logic layer memory cells, and one arithmetic logic gate of the plurality of arithmetic logic gates, corresponding to the one memory cell. Multiple unit cells, of the plurality of unit cells may represent a memory array configured to perform a matrix operation sharing a data line of the corresponding memory cells.

The apparatus may include one or more static random access memory (SRAM) crossbar arrays, wherein the unit cell corresponds to one bit cell of one of the SRAM crossbar arrays.

The memory layer may include a plurality of word lines, a plurality of bit lines intersecting with the plurality of word lines, and the corresponding memory cells being disposed at intersecting points between the plurality of word lines and the plurality of bit lines.

The logic layer may include a metal layer and plural with multiple vias of the plurality of vias being disposed to interconnect the multiple transistors to the first values stored in the corresponding memory cells.

The apparatus may also a second memory layer, the second memory layer being vertically stacked on an upper end of the logic layer connected to a respective gate terminal of the plurality of transistors, and the second memory layer may be vertically stacked by a back-end-of-line (BEOL) process, and 3-D stacked by one of a through silicon via (TSV) method or a monolithic method.

The apparatus may also include a second memory layer, the second memory layer being vertically stacked on an upper end of the logic layer connected to a respective gate terminal of the plurality of transistors, the second memory layer may include a plurality of second layer memory cells, multiple second layer memory cells of the plurality of second layer cells may respectively store second values, and the respective multiplier operations of the multiple transistors may be performed with respect to the first values and the second values input to the plural transistors in the vertical direction through respective vias formed in the logic layer.

The apparatus may also include an adder layer including an adder tree configured to perform an add operation with respect to the multiplier operation results, the adder layer being vertically stacked on an upper end of the logic layer.

The adder layer may be vertically stacked by a back-end-of-line (BEOL) process, the adder tree being 3D-stacked by one of a through silicon via (TSV) method or a monolithic method, and the adder tree being connected to an output node of respective ones of the multiple transistors in a vertical direction.

The apparatus may be an electronic device, and is a mobile device, a mobile computing device, a mobile phone, a smartphone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, or a medical device.

In a general aspect, here is provide an electronic device including an array circuit including a plurality of the 3D IMC devices and a controller configured to implement a neural network through a provision of input second values to each of the plurality of 3D IMC devices and control of the plurality of 3D IMC devices, each of the 3D IMC devices including a memory layer including a plurality of front-end-of-line (FEOL) memory cells, and a logic layer including plural arithmetic logic gates including a plurality of back-end-of-line (BEOL) transistors, the plurality of BEOL transistors being vertically stacked on respective output ends of the plurality of memory cells, wherein each of plural transistors of the plurality of BEOL transistors operates as a multiplier and is configured to provide an operation result with respect to first values stored in corresponding memory cells of the plurality of memory cells.

The device may also include a second memory layer, where the second memory layer may be vertically stacked on an upper end of the logic layer connected to a respective gate terminal of the plurality of transistors, and the second memory layer may be vertically stacked a back-end-of-line (BEOL) process. The first values and the second values may be input to the plural transistors in the vertical direction through respective vias formed in the logic layer.

The device may also include an adder layer including an adder tree configured to perform an add operation with respect to the multiplier operation results, the adder layer being vertically stacked by a back-end-of-line (BEOL) process, the adder tree may be 3D-stacked by one of a through silicon via (TSV) method or a monolithic method, and the adder tree may be connected to an output node of respective ones of the plural transistors in the vertical direction.

In a general aspect, here is provided a method including storing first values in static read-only access memory (SRAM) cells of a front-end-of-line (FEOL) memory array, applying second values respectively corresponding to memory cells for a multiplication and accumulation (MAC) operation to arithmetic logic gates including back-end-of-line (BEOL) transistors, transmitting and summing operation results respectively corresponding to the memory cells, and outputting a result of a summation from the summing.

The arithmetic logic gates may be disposed vertically over respective SRAM cells.

In another general aspect, here is provided a method including forming a memory layer including memory cells, the memory cells being formed by a front-end-of-line (FEOL) process, and forming a logic layer including an input and a plurality of transistors, each transistor of the plurality of transistors being formed by a back-end-of-line (BEOL) process, and each transistor being vertically formed with the memory layer on upper ends of respective memory cells. The forming of the memory layer and/or the logic layer includes respective connecting each memory of the plurality of memory cells to a corresponding transistor of the plurality of transistors.

The method may also include each transistor to an adder tree to provide an operation result with the respective memory cells to the adder tree and each transistor may operate as a multiplier.

The method may include forming a second memory layer vertically over the logic layer by a BEOL process, and second memory cells of the second memory layer being connected to respective gate terminals of the plurality of transistors.

Other features and aspects will be apparent from the following detailed description, the drawings, and the claims.

### BRIEF DESCRIPTION OF THE DRAWINGS

FIG. 1 illustrates an example of a relationship between operations performed in an in-memory computing (IMC) device and a neural network according to one or more embodiments.

FIGS. 2A and 2B illustrate examples of a three-dimensional (3D) IMC device and a crossbar array including the 3D IMC device according to one or more embodiments.

FIG. 3 illustrates an example of a front-end-of-line (FEOL) process and a back-end-of-line (BEOL) process according to one or more embodiments.

FIG. 4 illustrates an example of a 3D IMC device according to one or more embodiments.

FIG. 5 illustrates an example of an operation of a 3D IMC device using a negatively doped metal-oxide semiconductor (n-MOS) BEOL transistor according to one or more embodiments.

FIG. 6 illustrates an example of an operation of a 3D IMC device using a positively doped metal-oxide semiconductor (p-MOS) BEOL transistor according to one or more embodiments.

FIG. 7 illustrates an example of a 3D IMC device with an additionally stacked external memory according to one or more embodiments.

FIG. 8 illustrates an example of a 3D IMC device with an additionally stacked adder tree according to one or more embodiments.

FIG. 9 illustrates an example of a computing device with 3D in-memory computing according to one or more embodiments.

FIG. 10 illustrates an example of an electronic device or system according to one or more embodiments.

FIG. 11 illustrates an example of an operating method of a 3D IMC device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

A CNN may be executed using one or more processors, where some operations, such as MAC (multiplication and accumulation) operations may be performed using in-memory computing.

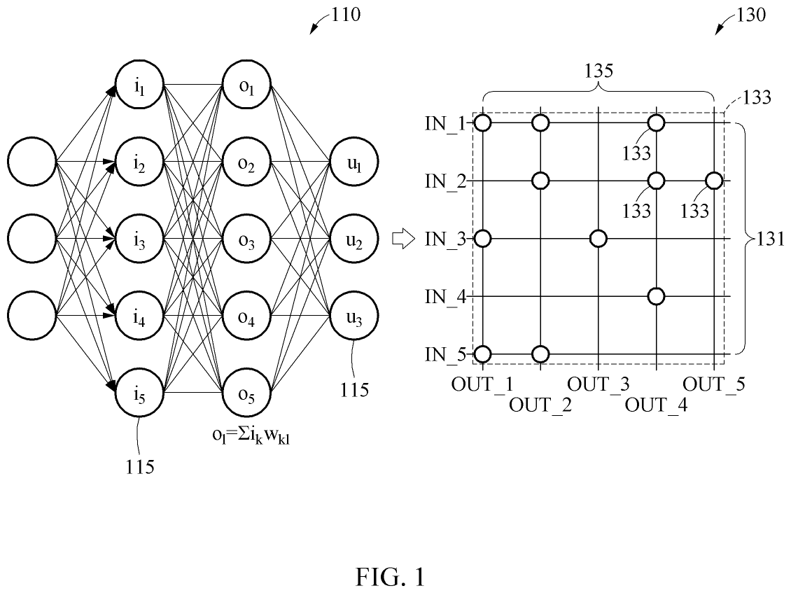

FIG. 1 illustrates an example of a relationship between operations performed in an in-memory computing (IMC) device and a neural network according to one or more embodiments. Referring to FIG. 1, a neural network 110 and a memory array 130 of an IMC device corresponding to the neural network 110 are illustrated while a neural network and neural network MAC operation will be discussed herein, this is only an example, and embodiments may include other machine learning models with a MAC or related operation, or where MAC operations or related operations are otherwise implemented.

IMC corresponds to a computing architecture that causes an operation to be performed directly in a memory, which may overcome limited performance and power issues due to frequent data movement between the memory and an operation unit (e.g., a processor), occurring in the von Neumann architecture. An IMC device may be divided into an analog IMC device and a digital IMC device according to which domain an operation is to be performed. The analog IMC device may, for example, perform an operation in an analog domain such as current, electric charge, time, and the like. The digital IMC device may use a logic circuit to perform an operation in a digital domain.

As a non-limiting example, the IMC device may accelerate a matrix operation and/or a multiplication and accumulation (MAC) (MAC) operation that performs an accumulation of results of multiple multiplications, such as when training or performing an inference operation of a trained artificial intelligence (AI) model. In this example, an operation of multiplication and summation for the neural network 110 may be performed through the memory array 130 including memory cells 133 in a memory element in an IMC device. Since the memory cell 133 may store a value corresponding to a bit, the memory cell 133 may be referred to as a bit cell.

The IMC device may perform the operation of multiplications and accumulation (e.g., addition or summation, as non-limiting examples) by the computing architecture of the memory array 130 including the memory cells 133 and operators (e.g., a multiplier) added to the memory array 130, as a non-limiting example, to implement processes of machine learning of the example neural network 110.

The neural network 110 may be, for example, a DNN or n-layer neural network including two or more hidden layers. For example, the neural network 110 may be a deep neural network (DNN) including an input layer (Layer 1), two hidden layers (Layer 2 and Layer 3), and an output layer (Layer 4). However, examples are not necessarily limited thereto. When the neural network 110 is implemented with a DNN architecture, the neural network 110 includes plural layers capable of processing information. The neural network 110 may process more complex data sets than a neural network having a single layer. Although FIG. 1 illustrates the neural network 110 including three layers as an example, the neural network 110 may include fewer or more layers or fewer or more channels. The neural network 110 may include layers in various architectures different from that illustrated in FIG. 1. In one or more examples, the DNN may be a convolutional neural network (CNN) or includes one or more convolutional layers or operations.

Each of the layers included in the neural network 110 may include a plurality of nodes 115. A node may correspond to a plurality of artificial nodes known as neurons, processing elements (PEs), units, channels, or other similar terms. The neural network 110 may include, for example, an input layer including three nodes, hidden layers respectively including five nodes, and an output layer including three nodes, but is not limited thereto. However, FIG. 1 is merely an example, and each of the layers included in the neural network 110 may include various numbers of nodes.

The nodes 115 included in each of the layers of the neural network 110 may be connected to one another to process data such as through weighted connectors. For example, one node may receive data from a same or other nodes to perform an operation and may output a result of the operation to other nodes (e.g., respectively one or more of previous layers, subsequent layers, parallel layers, a same layer, and/or from an exterior of the network).

A plurality of nodes 115 may be connected to nodes of another layer through one or more respective connection lines or weighted connections, wherein each weight w may be set for each connection line. For example, an output o₁ of one node may be determined based on input values (e.g., i₁, i₂, and i₃) propagated from other nodes of a previous layer connected to the node and on weights w₁₁, w₂₁, w₃₁, and w₄₁ of connection lines from the previous layer to the node.

For example, an l-th output of among L output values may be represented by Equation 1 below. In this example, “L” may be an integer greater than or equal to “1” and “1” may be an integer greater than or equal to “1” and less than or equal to “L”.

oₗ=Σiₖwₖₗ Equation 1:

In Equation 1, iₖ may denote a k-th input among P inputs and wₖₗ may denote a weight set between the k-th input and the l-th output. In this example, P may be an integer greater than or equal to “1” and k may be an integer greater than or equal to “1” and less than or equal to P. In one or more examples, Equation 1 may further include an activation function that is applied to the result of the summation.

In other words, an output from nodes 115 in the neural network 110 may be expressed as a weighted sum between each respective input i and weight w. The weighted sum may be a multiplication operation and an iterative accumulation (or summation) operation between a plurality of inputs and a plurality of weights, and may also be referred to as a multiplication and accumulation (MAC) operation. Since a MAC operation is performed using a memory to which a computing function is added, example circuits or circuitry herein for performing a MAC operation may be referred to as an “IMC device”.

The neural network 110 may, for example, perform a weighted sum operation in layers based on input data (e.g., i₁, i₂, i₃, i₄, and i₅) and generate output data (e.g., u₁, u₂, and u₃) based on a result (e.g., o₁, o₂, o₃, o₄, and o₅) of performing the operation.

The IMC device may be a MAC operator in which the memory array 130 is configured as a crossbar array.

The memory array 130 may include a plurality of word lines 131, the plurality of memory cells 133, and a plurality of bit lines 135.

The plurality of word lines 131 may be used to receive input data of the neural network 110. For example, when the plurality of word lines 131 are N word lines (N being a predetermined natural number), a value corresponding to the input data of the neural network 110 may be applied to the N word lines.

The plurality of word lines 131 may intersect with the plurality of bit lines 135. For example, when the plurality of bit lines 135 are M bit lines (M being a predetermined natural number), the plurality of bit lines 135 and the plurality of word lines 131 may intersect at N×M intersecting points.

In addition, the plurality of memory cells 133 may be disposed at the intersecting points between the plurality of word lines 131 and the plurality of bit lines 135. Each of the plurality of memory cells 133 may be implemented as, for example, volatile memory such as static random-access memory (SRAM) to store weights. However, examples are not necessarily limited thereto. According to an example, each of the plurality of memory cells 133 may be implemented as non-volatile memory such as resistive random-access memory (ReRAM), eFlash, or the like.

The word lines 131 may be referred to as “row lines” in that they correspond to rows that are arranged in a horizontal direction in the memory array 130. The bit lines 135 may be referred to as “column lines” in that they correspond to columns that are arranged in a vertical direction in the memory array 130. Hereinafter, the terms “word line(s)” and “row line(s)” may be used interchangeably. Furthermore, the terms “bit line(s)” and “column line(s)” may be used interchangeably.

The plurality of word lines 131 may sequentially receive the value corresponding to the input data of the neural network 110. In this case, the input data may be, for example, input data included in an input feature map or a weight value stored in a weight map.

For example, when an input signal IN_1 for the IMC device is “1” or “high”, the input signal IN_1 may be applied to a first word line of the memory array 130 in a first cycle corresponding to the input signal IN_1. When an input signal IN_2 for the IMC device is “0” or “low”, the input signal IN_2 may be applied to a second word line of the memory array 130 in a second cycle corresponding to the input signal IN_2.

Sequentially inputting the input signals for the IMC device to the plurality of word lines 131 of the memory array 130 may be intended to prevent two or more input signals from colliding on the same bit line. If no collision occurs on the same bit line, the IMC device may simultaneously input two or more input signals to the word lines 131.

Each of the plurality of memory cells 133 of the memory array 130 may be disposed at an intersecting point of a word line and a bit line corresponding to the memory cell. Each of the plurality of memory cells 133 may store data corresponding to 1 bit. Each of the plurality of memory cells 133 may store weight data of a weight map or input data of an input feature map.

Each of the plurality of memory cells 133 may store a bit value in an intersecting point of a corresponding word line and a corresponding bit line based on weight data corresponding to the memory cell. For example, when a weight corresponding to a memory cell (i, j) is “1”, the weight “1” may be stored in an intersecting point of a word line i and a bit line j corresponding to the memory cell (i, j). Alternatively, when a weight corresponding to a memory cell (i+1, j+1) is “0”, a weight “0” may be stored in an intersecting point of a corresponding word line i+1 and a corresponding bit line j+1.

In the example of FIG. 1, a weight corresponding to a memory cell (1, 1) corresponding to a first word line and a first bit line is “1”, and thus, the weight “1” may be stored in the memory cell (1, 1) corresponding to an intersecting point of the first word line and the first bit line. In this example, an input signal IN_1 input to the first word line may be transmitted to the first bit line.

Alternatively, a weight corresponding to a memory cell (1, 3) corresponding to the first word line and the third bit line is “0”, and thus, the weight “0” may be stored in the memory cell (1, 3) corresponding to an intersecting point of the first word line and the third bit line. In this example, the input signal IN_3 input to the first word line may not be transferred to the third bit line.

The memory cells 133 may include, for example, any one or any combination of a diode, a transistor (e.g., a metal-oxide-semiconductor field-effect transistor (MOSFET)), an SRAM memory cell, and a resistive memory. However, examples are not necessarily limited thereto. Hereinafter, a description is provided based on an example that the memory cells 133 are SRAM memory cells. However, the example is not limited thereto.

The plurality of bit lines 135 may intersect with the plurality of word lines 131, and each of the bit lines 135 may output a value received from a corresponding input line through a corresponding memory cell.

Among the plurality of memory cells 133, memory cells disposed along the same word line may receive the same input signal and memory cells disposed along the same bit line may transmit the same output signal.

Considering the memory cells 133 disposed in the memory array 130 illustrated as an example in FIG. 1, the IMC device may perform a MAC operation corresponding to, or effectively according to, Equation 2 below.

$$[ \begin{matrix}OUT\_ 1 \\ OUT\_ 2 \\ OUT\_ 3 \\ OUT\_ 4 \\ OUT\_ 5\end{matrix} ] = [ \begin{matrix}1 & 0 & 1 & 0 & 1 \\ 1 & 1 & 0 & 0 & 1 \\ 0 & 0 & 1 & 0 & 0 \\ 1 & 1 & 0 & 1 & 0 \\ 0 & 1 & 0 & 0 & 0\end{matrix} ] [ \begin{matrix}IN\_ 1 \\ IN\_ 2 \\ IN\_ 3 \\ IN\_ 4 \\ IN\_ 5\end{matrix} ] \qquad Equation 2$$

Bitwise multiplication operations may be performed and accumulated by each of the memory cells 133 included in the memory array 130 of the IMC macro, whereby a MAC operator or an AI accelerator may be implemented.

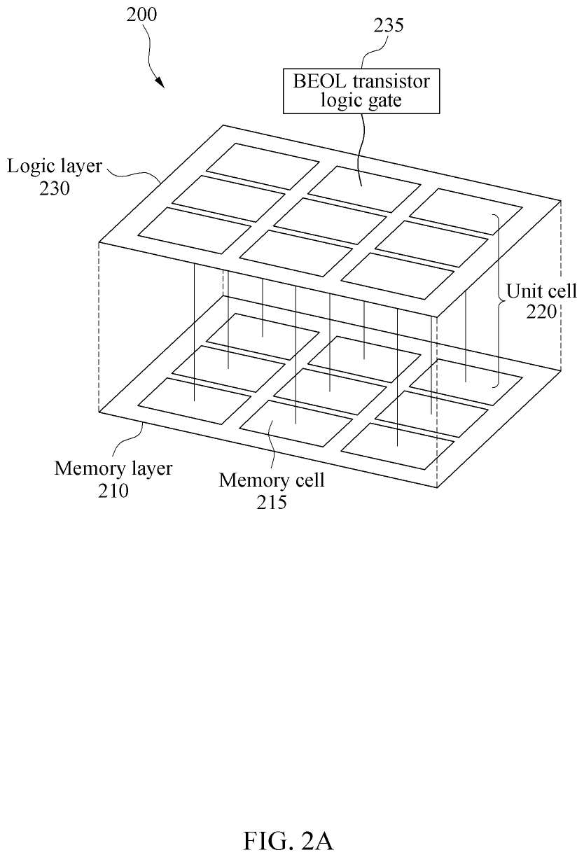

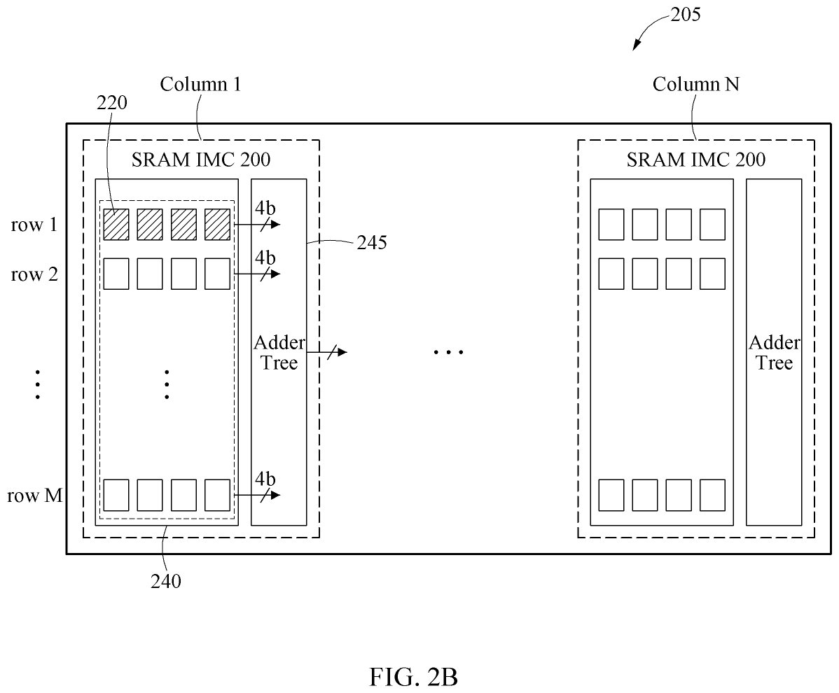

FIGS. 2A and 2B illustrate an examples of 3D IMC devices and crossbar arrays including a 3D IMC device according to one or more embodiments.

Referring to FIG. 2A, a structure of a 3D IMC device 200 including a memory layer 210 and a logic layer 230 is illustrated. The 3D IMC device 200 may include an adder tree (e.g., an adder tree 245 of FIG. 2B) and a memory array (e.g., a memory array 240 of FIG. 2B) including the memory layer 210 and the logic layer 230. As illustrated in FIG. 2B, the 3D IMC device 200 may include an adder tree 245 corresponding to one memory array 240.

The memory layer 210 may include memory cells 215 implemented by a front-end-of-line (FEOL) process. A memory cell 215 implemented by the FEOL process may also be referred to as a “FEOL memory cell”. The memory cells 215 may store first values. The first values, for example, may correspond to weights, however they are not limited thereto.

The logic layer 230 may include arithmetic logic gates 235 including transistors vertically stacked on the upper end of the memory cells 215, wherein the transistors are implemented by a back-end-of-line (BEOL) process. Hereinafter, for ease of description, a transistor implemented by a BEOL process may be simplified as a “BEOL transistor”. In this description, unless otherwise specified, it may be understood that a transistor refers to a BEOL transistor.

The logic layer 230 may include a metal layer and vias for interconnecting the first values stored in the memory layer 210 to the transistors.

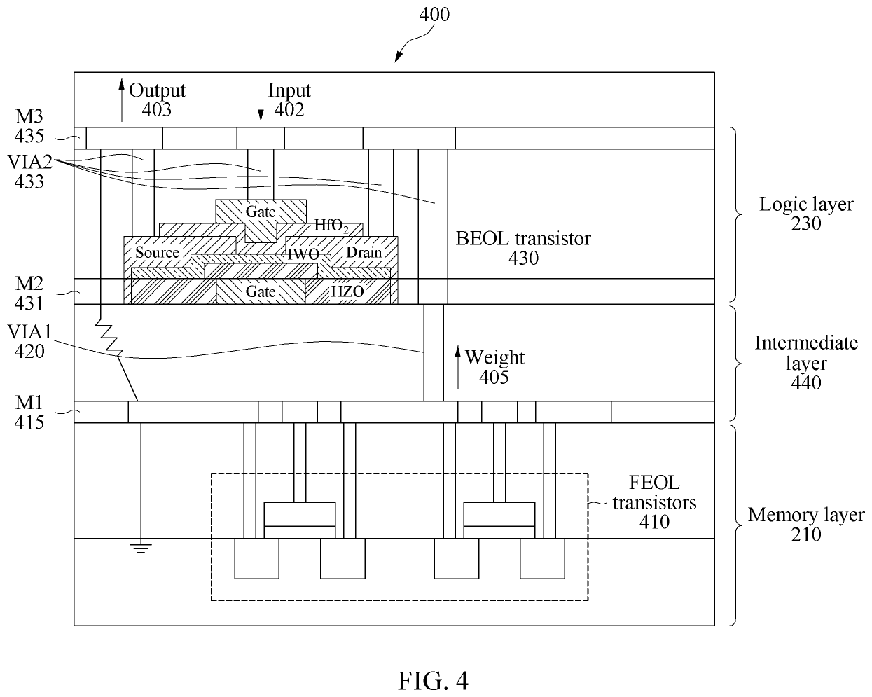

Each of the transistors that may make up the arithmetic logic gates 235 may function as an operator (e.g., a multiplier) and may provide or transmit, to the adder tree 245 illustrated in FIG. 2B, operation results with the memory cells 215 corresponding to the transistors, respectively. In this example, a “corresponding memory cell” corresponding to each of the transistors may be a memory cell disposed in the vertical direction to the bottom of the transistor and may be understood as a memory cell that transmits/receives data to or from a transistor through a via and/or a metal line, as illustrated in FIG. 4 described below. A connection relationship between the memory layer 210 and the logic layer 230 is described with reference to FIG. 4.

In an example, since a transistor implemented by the BEOL process performs a function of an operator, when an input and a weight are input to the transistor, the transistor may perform an IMC function and may thus have versatility.

The transistors may include, for example, various transistors implemented by the BEOL process, such as a thin film transistor (TFT), a ferroelectric field-effect transistor (FeFET), a two-dimensional (2D) field effect transistor (FET), and/or a polycrystalline silicon (poly-Si) channel FET, however examples are not limited thereto.

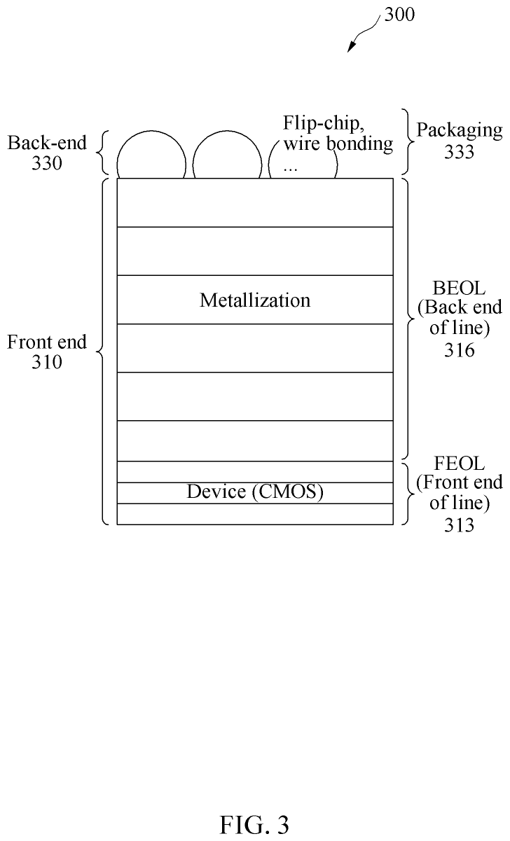

The FEOL process and the BEOL process are described with reference to FIG. 3, as a non-limiting example.

Each of the arithmetic logic gates 235 may be, for example, a transistor configured to perform an AND logic operation corresponding to a multiplier. One arithmetic logic gate may be, for example, configured by one BEOL transistor, however the example is not limited thereto. In an example, the spatial efficiency of an IMC may be increased because the area occupied by the IMC may decrease by configuring an arithmetic logic gate, such as a multiplier, by using one BEOL transistor.

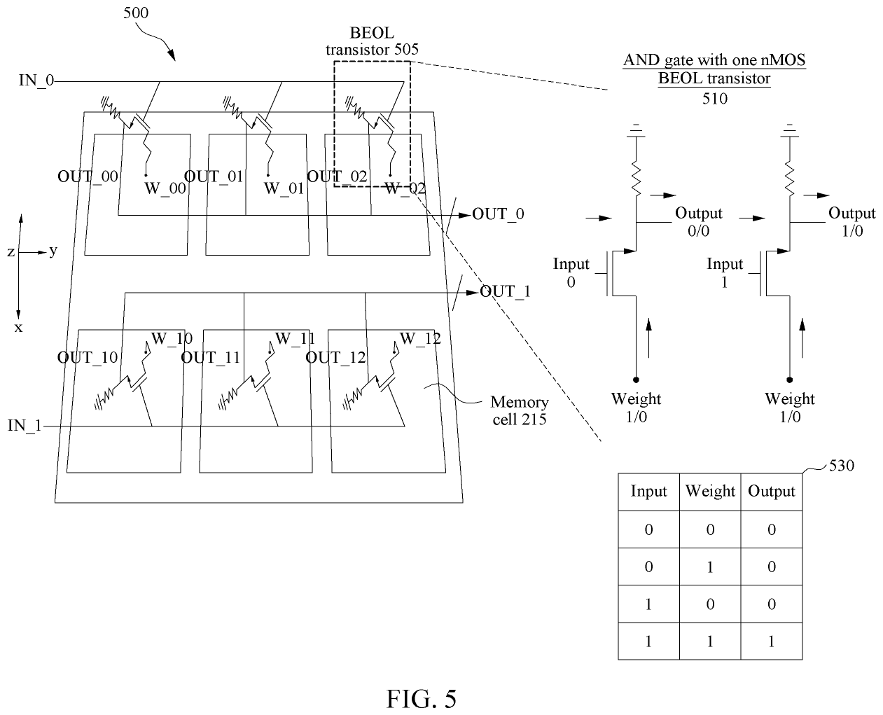

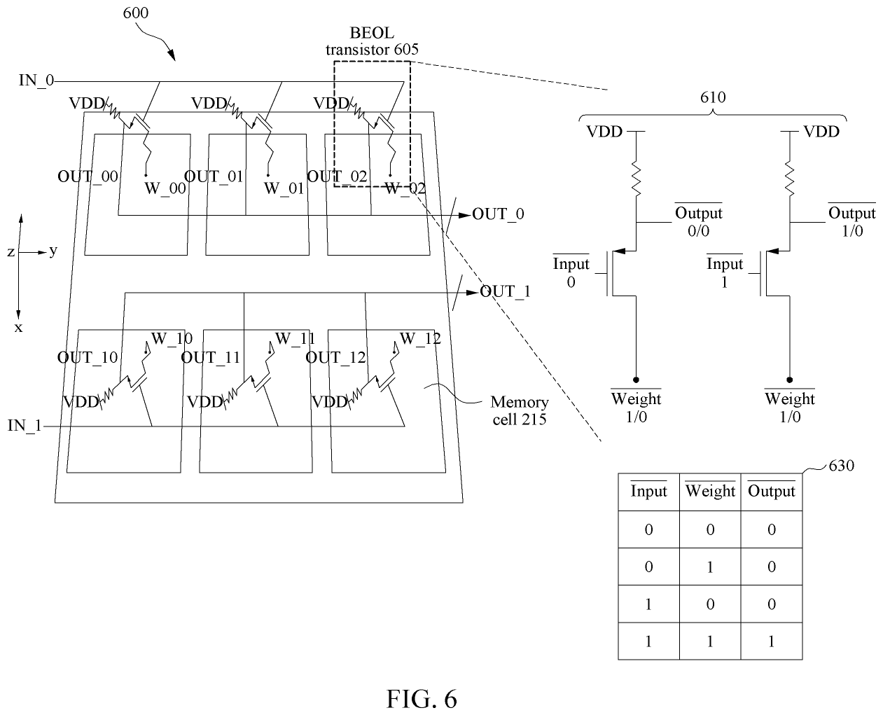

The arithmetic logic gates 235 may be vertically stacked to respectively correspond to the memory cells 215. A transistor including one arithmetic logic gate may be, for example, a negatively doped metal-oxide semiconductor (n-MOS) transistor, or a positively doped-MOS (p-MOS) transistor. An example of a transistor with an arithmetic logic gate with an n-MOS transistor is described below with reference to FIG. 5. In addition, an example of transistor with an arithmetic logic gate with a p-MOS transistor is described below with reference to FIG. 6.

One memory cell included in the logic layer 230 and an arithmetic logic gate corresponding to the memory cell that may make up a unit cell 220 of the memory array 240 of the 3D IMC device 200. The unit cell 220 may include one bit cell of the memory array 240 that may perform a matrix operation sharing a data line of the memory cells 215.

The 3D IMC device 200 may improve a spatial, or area, efficiency and the degree of integration by reducing the size of a MAC operator that includes a memory and a multiplier to the size of a memory through a structure in which the logic layers 230 having BEOL transistors are vertically stacked on the memory cell 215.

Referring to FIG. 2B, a 4 bit-M×N crossbar array 205 according to an example may include one or more SRAM 3D IMC devices, such as the 3D IMC device 200, of FIG. 2A, each SRAM 3D IMC device 200 including a memory array 240 and an adder tree 245 for each column.

The memory array 240 may include the memory layer 210 and the logic layer 230 described above with reference to FIG. 2A. For example, the memory array 240 may include, for N columns of the crossbar array 205, M rows including four unit cells 220 by each column for a 4-bit operation. For example, four unit cells 220 may be arranged in a row direction and may be grouped by one word line of the crossbar array, however the example is not limited thereto.

As described above, the unit cell 220 may include the SRAM memory cell and the arithmetic logic gate 235 corresponding to a multiplier. The unit cell 220 may correspond to one bit.

In the crossbar array 205, one adder tree 245 may exist in each column and the adder tree 245 may sum an output result of each column for a matrix multiplication operation. By this way, the M×N crossbar array 205 may include an arrangement of N 3D IMC devices 200 having N columns.

For example, in response to input data in the row direction, an operation between the input data and a value stored in a bit cell (e.g., the unit cell 220) in the memory array 240 may be performed by the arithmetic logic gate 235 and an operation result of the arithmetic logic gate 235 may be output to the adder tree 245 in the row direction. The adder tree 245 may sum all operation results which are output in each row direction of the memory array 240.

FIG. 3 illustrates an example of an FEOL process and a BEOL process according to one or more embodiments. Referring to FIG. 3, a diagram 300 dividing a front-end 310 and a back-end 330 is illustrated. In addition, FIG. 3 also illustrates processes according to an embodiment in which the front-end 310, the back-end 330 and a packaging 333 are assembled.

The front-end 310 may be a part where a metallizing process with a device (e.g., a complementary metal-oxide semiconductor (CMOS)) in an integrated circuit (IC) is performed. For example, in the front-end 310, generating a part corresponding to a physical cell and/or a logic gate, such as a NAND, an OR, a NOR, an AND, a BUFFER, and an INVERT may be assembled or formed in an FEOL process 313.

The FEOL process 313 may be a process of establishing a structure of a transistor TR in a semiconductor fabrication (hereinafter, referred to as fab) process, and may form, for example, a wafer, a shallow trench isolation (STI), a well formation, a gate module, and/or a source and drain module.

When the FEOL process 313 is completed, a BEOL process 316 may proceed and then, packaging 333 may be performed. The BEOL process 316 may be the assembly or formation of the back-end 330. In this example, based on the processing order of the process, the FEOL process 313 may be referred to as a “fab preprocessing” and the BEOL process 316 may be referred to as a “fab post-processing”.

After the FEOL process 313 is completed, lines of a wiring process may be disposed wherein the lines may connect devices in signal and power aspects. The lines of the wiring process may include, for example, various oxide films and/or metals, and lines for a signal, clock, and/or power may be connected to the BEOL process 316 through various layers. A process of generating lines of the wiring process which are configured to connect devices in a signal and power aspect after the FEOL process 313 in the front-end 310 may be referred to as the BEOL process 316.

In the BEOL process 316, wirings and an insulating film may be arranged based on a design and a fab process may be completed by performing a passivation process to cover a surface of a semiconductor chip with a protective film.

The various transistor terminals assembled through the FEOL process 313 and the wirings formed by the BEOL process 316 may be connected to or on one another by bonding of silicon and metal. However, since a transistor may not perform its own function by simple bonding of silicon and metal, a bonding layer (e.g., an intermediate bonding layer 440 of FIG. 4) in a new intermediate type called silicide may be arranged such that a current that is proportional to a voltage may be induced to normally flow between the silicon and metal.

A material used in the wiring process in the BEOL process 316 may be copper (Cu), aluminum (Al), silver (Ag), and/or gold (Au), however the material is not limited thereto. For example, in the BEOL process 316, silicide and a dielectric (a dielectric or an insulator) stacking, making holes in a poly-metal dielectric (PMD) (for interconnection; vias), metal layer stacking, dielectric (inter-metal dielectric (IMD)) stacking, forming a via, and/or chemical vapor deposition (CVD) processing may be performed, however the example is not limited thereto.

The back-end 330 may be, for example, understood as a part configured to perform the packaging 333 through flip-chip bonding and/or wire bonding. The packaging 333 may refer to molding by installing a chip in a substrate where an outer lead is formed.

The outer lead may be a terminal configured to electrically connect a substrate to a chip and wire bonding and flip-chip bonding may be determined based on a connection type of the outer lead and the chip.

The wire bonding may be a method of connecting an electrode pattern of a semiconductor chip to an inner lead electrically connected to the outer lead using a fine wire while the chip is placed on the substrate where a lead is formed.

The flip-chip bonding may be a method of generating a protrusion, such as a solder ball, in an electrode pattern or an inner lead and electrically connecting a substrate to a chip through the solder ball when the chip is placed on the substrate.

FIG. 4 illustrates an example of a 3D IMC device according to one or more embodiments. Referring to FIG. 4, a diagram 400 to explain a connection relationship between the memory layer 210 and the logic layer 230 of a 3D IMC device is illustrated according to an example.

In the 3D IMC device, a transistor (e.g., a BEOL transistor 430) that operates as an operator (e.g., a multiplier) may be stacked in the vertical direction rather than a planar direction on a memory cell. In an example, the degree of integration of the 3D IMC device may be improved by reducing the area of a unit cell (including a memory cell and an operator (e.g., the BEOL transistor 430)) of the 3D IMC device to the area occupied by the memory cell when an area occupied by the BEOL transistor 430 is smaller than the memory cell by vertically stacking an arithmetic gate (e.g., an AND gate and/or a NAND gate) corresponding to an operator and directly connecting the arithmetic logic gate to the memory cell by configuring the arithmetic logic gate in one BEOL transistor 430. In addition, as the area of the 3D IMC device decreases, the size of other on-chip memory and neighboring circuits and/or the degree of integration may increase.

The memory layer 210 may include an FEOL transistor 410 implemented by an FEOL process and may store, for example, a weight 405 for a MAC operation. In this example, the weight 405 may correspond to an output of the FEOL transistor 410. The weight 405 may be input to a drain terminal of the BEOL transistor 430 through a via 1 420.

An arithmetic logic gate for a MAC operation may be formed in the logic layer 230 and the arithmetic logic gate may be, for example, configured by the BEOL transistor 430. The BEOL transistor 430 may be, for example, a FeFET, however is not limited thereto.

The logic layer 230 may receive an input 402 by being connected to an external input data line and may transmit an output 403 corresponding to a result of an operation of the BEOL transistor 430 to the outside through a metal layer M3 435. In this example, vias 2 433 may be formed and respectively configured to connect a source terminal, a gate terminal, and a drain terminal of the BEOL transistor 430 to the metal layer M3 435.

In FIG. 4, the input 402 may be input to the gate terminal of the BEOL transistor 430. In this example, since a line width of the BEOL transistor 430 is greater than a line width of the FEOL transistor 410, an access signal decay may be reduced since a resistance in the BEOL transistor 430 decreases.

The output 403 may be output from a node in a resistor connected to the source terminal on the upper end of the BEOL transistor 430. Thus, latency and signal decay which may occur while transmitting the output 403 of the BEOL transistor 430 to the adder tree to calculate a final operation result may be reduced.

An intermediate bonding layer 440 may include metal lines (e.g., M1 415 and M2 431) and/or vias (e.g., VIA 1 420) to interconnect the FEOL transistor 410 in the memory layer 210 to the BEOL transistor 430 in the logic layer 230. The intermediate bonding layer 440 may be referred to as an intermediate layer.

The intermediate bonding layer 440 may provide an interconnection between the wirings implemented by the BEOL process in the logic layer 230 and the terminals of the FEOL transistor 410 implemented by the FEOL process in the memory layer 210.

The intermediate bonding layer 440 may be, for example, a silicide layer that may bond—silicon and metal, however the example is not limited thereto.

The area efficiency may improve by reducing an area of a MAC operator included in a memory and a multiplier to include an area of a memory through a vertical structure in which the logic layer 230 made up of the BEOL transistor(s) 430 is vertically stacked on the memory layer 210.

For example, in an example when a MAC operator includes a 6T SRAM and a 4T multiplier, the resulting 3D IMC device may occupy an area corresponding to the 6T SRAM because the logic layer corresponding to the 4T multiplier is vertically stacked on a memory layer corresponding to the 6T SRAM, and thus, the area may be reduced by about 30%.

In addition, in an example, a resistance-capacitance (RC) delay may be decreased by routing the input 402, the output 403, and the weight 405 through the BEOL line and the vias. A reduction in the rate of the RC delay may increase as its memory array expands.

In an example, data movement to an arithmetic logic gate corresponding to a multiplier which moves along a BEOL metal line (e.g., M1 415 and/or M2 431) may proceed in such a manner so as to allow a latency to also decrease.

FIG. 5 illustrates an example of an operation of a 3D IMC device using an n-MOS BEOL transistor according to one or more embodiments. Referring to FIG. 5, a circuit of a 3D IMC device 500 in a monolithic structure with a BEOL transistor 505 is illustrated according to an example.

The 3D IMC device 500 may implement a 3D-stack, by the monolithic structure, where the BEOL transistor 505 is implemented by a BEOL process on the upper end of the memory cell 215 and integrated by an FEOL process. The BEOL transistor 505 may be, for example, an n-MOS BEOL transistor. In this example, the BEOL transistor 505 may be, for example, a BEOL transistor of which a channel is n-type which may be an AND gate that operates as a multiplier. The BEOL transistor 505 may be directly connected to the memory cell 215. The multiplier may be the BEOL transistor 505 or a plurality of BEOL transistors, as necessary.

Referring to diagram 510, a circuit of an AND gate with the BEOL transistor 505 is illustrated. In the diagram 510, a gate terminal of the BEOL transistor 505 may be connected to an input data line Input. A drain terminal of the BEOL transistor 505 may be connected to the memory cell 215 corresponding to the BEOL transistor 505 of the memory cells. A source terminal of the BEOL transistor 505 may be grounded through a resistor.

An operation result of the BEOL transistor 505 may correspond to an operation result of a multiplier and may be output to the outside through an output node Output disposed between the resistor and the source terminal of the BEOL transistor 505.

In this example, a voltage difference between the gate terminal and the drain terminal of the BEOL transistor 505 may allow the BEOL transistor 505 to perform an AND operation as shown in a table 530. For example, when a voltage corresponding to an input “0” is applied to the gate terminal of the BEOL transistor 505, the Output of the BEOL transistor 505 may output “0” based on the ground connected to the source terminal of the BEOL transistor 505 regardless of the voltage of the drain terminal of the BEOL transistor 505.

On the other hand, when a voltage corresponding to “1” is applied to the gate terminal of the BEOL transistor 505, an output value of the BEOL transistor 505 may be determined based on a voltage of the drain terminal of the BEOL transistor 505. For example, a voltage corresponding to “1” may be applied to the gate terminal of the BEOL transistor 505. In this example, when the voltage of the drain terminal of the BEOL transistor 505 corresponds to “1”, an output value of the BEOL transistor 505 may be “1” and when the voltage of the drain terminal of the BEOL transistor 505 corresponds to “0”, an output value of the BEOL transistor 505 may be “0”.

All output values of the BEOL transistor 505 may move to the adder tree and may be used to calculate a final output value of a MAC operation. In this example, a resistance value connected to the source terminal of the BEOL transistor 505 to clearly obtain an output signal of the BEOL transistor 505 may be sufficiently larger than a resistance value of the BEOL transistor 505 in an “on state”.

A plurality of memory cells 215 of the 3D IMC device 500 may be configured in an array type. The 3D IMC device 500 may be, for example, a digital SRAM IMC device.

For example, when the 3D IMC device 500 receives input data of a second value (e.g., “0” or “1”) in the row direction, the 3D IMC device 500 may perform a multiplication operation between the second value that is the input data and a first value (e.g., “0” or “1”) stored in each memory cell. In other words, an AND operation may be performed on the input data. The 3D IMC device 500 may transmit the multiplication operation result (e.g., “0” or “1”) between the first value and the second value to the adder tree through a bus. An operation of the 3D IMC device 500 to transmit a multiplication operation result, in other words, the AND operation result, may be performed by each row of a memory array and may enable the adder tree to simultaneously perform a MAC operation.

In the 3D IMC device 500, input data (e.g., IN_0 and IN_1) may be applied to the gate terminal of the BEOL transistor 505 in the row direction of the memory array including the memory cells 215. In this example, weights W_00 and W_10 may be stored in the memory cells 215 of the first row of the memory cells in the row direction of the memory array. The weights W_00 and W_10 stored in the memory cells 215 may be connected to the drain terminal of the BEOL transistor 505. Each memory cell may perform an AND operation based on the input data and the weight, and a result value (e.g., OUT_00 and OUT_10) of the AND operation may output from each memory cell. In this example, result values of AND operations output by each row of the memory array may be transferred to the adder tree and may be used to calculate a final output value of a MAC operation.

By expanding the process described above, the 3D IMC device 500 may simultaneously obtain multiple pieces of output data in response to one piece of input data by including the memory cells 215 in a plurality of column units sharing the same input data that is provided in the row direction to the memory array. The 3D IMC device 500 may simultaneously obtain result values (e.g., OUT_00, OUT_01, and OUT_02) obtained by performing an AND operation between input data IN_0 and a weight (e.g., W_00, W_01, and W_02) of the memory cells 215 existing in the same row. Similarly, the 3D IMC device 500 may simultaneously obtain operation results (e.g., OUT_10, OUT_11, and OUT_12) for input data (e.g., IN_0) of a different row.

The 3D IMC device 500 may enable a multi-bit operation processing by transmitting an operation result transmitted by each row of the memory array to the adder tree through a bus.

FIG. 6 illustrates an example of an operation of a 3D IMC device using a p-MOS BEOL transistor according to one or more embodiments. Referring to FIG. 6, a circuit of a 3D IMC device 600 in a monolithic structure with a p-MOS BEOL transistor 605 is illustrated according to an example.

The 3D IMC device 600 may implement a 3D-stack, by the monolithic structure, where the BEOL transistor 605 is implemented by a BEOL process on the upper end of a memory cell 215 and integrated by an FEOL process. In this example, the BEOL transistor 605 may be, for example, a BEOL transistor of which a channel is p-type, and may be a NAND gate (or an AND gate) that operates as a multiplier. The BEOL transistor 605 may be directly connected to the memory cell 215.

Referring to diagram 610, a circuit of an AND gate with the BEOL transistor 605 is illustrated.

In the diagram 610, a gate terminal of the BEOL transistor 605 may be connected to an input data line Input. A drain terminal of the BEOL transistor 605 may be connected to a memory cell corresponding to an arithmetic logic gate of the memory cells 215. A voltage source (VDD) may be connected to a source terminal of the BEOL transistor 605. In this case, connection of the VDD to the source terminal of BEOL transistor 605 may be a difference between the n-MOS BEOL transistor 505 described above with reference to FIG. 5 and the p-MOS BEOL transistor 605. The BEOL transistor 605 may output an operation result through an output node disposed between the source terminal of BEOL transistor 605 and a resistor.

The structure of the 3D IMC device 600 including the BEOL transistor 605 may be similar to the structure of the 3D IMC device 500 including the BEOL transistor 505 described above with reference to FIG. 5.

Referring to the diagram 610, an input is connected to the gate terminal of the BEOL transistor 605 and a weight may be connected to the drain terminal of the BEOL transistor 605. In addition, the source terminal of the BEOL transistor 605 may be connected to the VDD through a resistor. An operation result may be output through the output node disposed between the resistor and the source terminal of the BEOL transistor 605.

For example, when an input and a weight are applied to the BEOL transistor 605, the BEOL transistor 605 may implement a function of an OR gate.

According to De Morgan's law, when a complement is applied to an input and a weight, an operation of an AND gate may be performed as Equation 3 shown below.

Ā+B̅=A̅B̅ Equation 3:

In other words, when inverted input data i̅n̅p̅u̅t̅ is applied to the gate terminal of the BEOL transistor 605 instead of non-inverted input data and an inverted weight w̅e̅i̅g̅h̅t̅ being applied to the drain terminal of the BEOL transistor 605 instead of a weight, the BEOL transistor 605 may thus perform an operation of an AND gate as illustrated in table 630. The BEOL transistor 605 may output inverted output data o̅u̅t̅p̅u̅t̅ as an operation result.

The 3D IMC device may therefore be implemented by simply replacing a multiplier that may be the n-type BEOL transistor 505 by a multiplier including the p-type BEOL transistor 605 by using the structure described above. This may indicate that a BEOL transistor may be used as a multiplier in all cases in which a channel of the BEOL transistor has a characteristic of an n-type or a p-type channel.

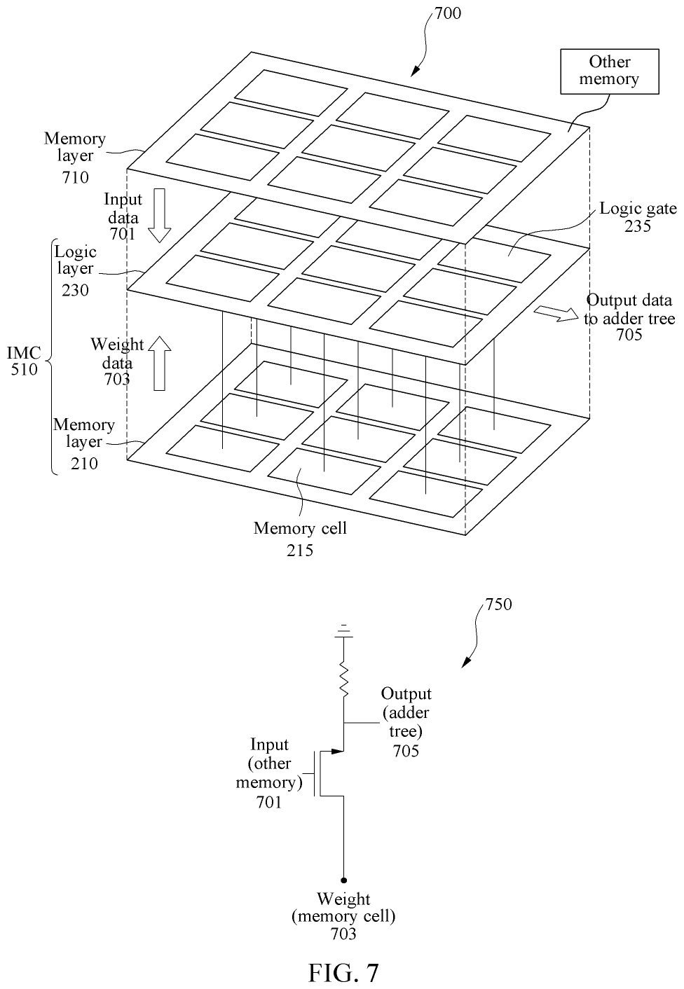

FIG. 7 illustrates an example of a 3D IMC device with an additionally stacked external memory according to one or more embodiments. Referring to FIG. 7, a structure of a 3D IMC device 700 in which a second memory layer 710, that is another memory (e.g., an external memory), is additionally stacked on the 3D IMC device 200 described above is illustrated.

The 3D IMC device 700 may include an additional second memory layer, that is, a second memory layer 710, along with the memory layer 210 and the logic layer 230 described above. The second memory layer 710, or memory cells of the second memory layer 710, may store second values. The second values may be, for example, input data, however the example is not limited thereto. According to an example, the second values may be weight data.

The second memory layer 710 may store the second values (e.g., input data 701) which are vertically input to BEOL transistors operating as the arithmetic logic gates 235. The second memory layer 710 may be connected to the gate terminal of the BEOL transistors of the logic layer 230 by being vertically stacked on the upper end of the logic layer 230 through a BEOL process and may transmit the second values (e.g., the input data 701) to the BEOL transistors of the logic layer 230.

The second memory layer 710 may be, for example, connected to the gate terminal of the transistors included in the logic layer 230 by being 3D-stacked on the upper end of the logic layer 230 by a through silicon via (TSV) method of a monolithic method. In this example, the TSV method may correspond to a wafer level packaging process and may be a chip-to-chip stacking method by forming a via in a semiconductor chip. The TSV method may reduce the length of interconnection between chips. The TSV method may also be referred to as a silicon wafer through-hole method. The monolithic method may correspond to a method of forming an interconnection with all circuit elements in (or on) a silicon substrate.

Both the second values (e.g., input data 701) stored in the second memory layer 710 and the first values (e.g., weight data 703) stored in the memory cell 215 of the memory layer 210 may be input to the arithmetic logic gate 235 of the logic layer 230. In other words, the BEOL transistor receives the first and second values in the vertical direction through a via formed in the logic layer 230. For example, as illustrated in diagram 750, an operation result 705 of the BEOL transistor receiving the input data 701 stored in the second memory layer 710 and the weight data 703 stored in the memory cell 215 of the memory layer 210 may be transmitted to the adder tree through an output node.

The 3D IMC device 700 may reduce latency due to data movement by reducing a moving path of data, compared to a planar 2D IMC device, by moving data between a plurality of layers through the vertical structure, such as 3D stacking, as opposed to a horizontal arrangement requiring a longer data path.

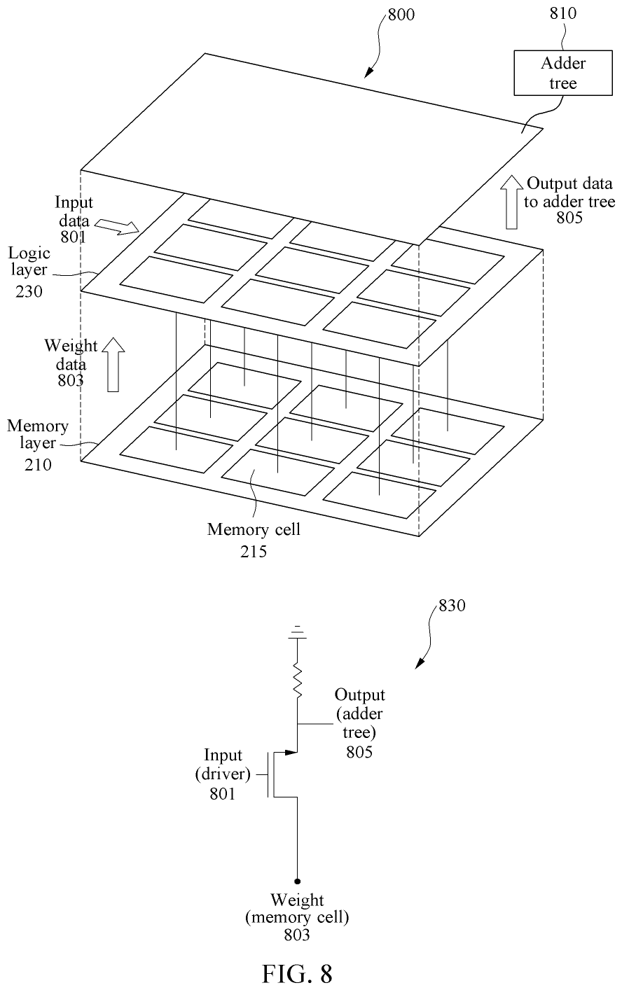

FIG. 8 illustrates an example of a 3D IMC device with an additionally stacked adder tree according to one or more embodiments. Referring to FIG. 8, a structure of a 3D IMC device 800 in which an adder layer 810 including an adder tree is additionally stacked on the 3D IMC device 200 described above with reference to FIG. 2 is illustrated.

The 3D IMC device 800 may additionally include an adder layer 810 along with the memory layer 210 and the logic layer 230 described above. The adder layer 810 may be vertically stacked on the upper end of the logic layer 230 through a BEOL process. An adder tree configured to perform an accumulation operation on an operation result of each of the memory cells 215 of the memory layer 210 may be formed in the adder layer 810.

The adder tree may be 3D-stacked on the upper end of the logic layer 230 by a TSV method, or a monolithic method in another example, and may be connected to an output node of the BEOL transistors of the logic layer 230.

All first values (e.g., weight data 803) stored in the memory cell 215 of the memory layer 210 may be vertically input to the BEOL transistor, in other words, the logic gate of the logic layer 230 through a via formed in the logic layer 230.

For example, as illustrated in diagram 830, the BEOL transistor may input output data 805 that is a MAC operation result between input data 801 input to the 3D IMC device 800 and weight data 803 transmitted by the memory layer 210, to the adder tree of the adder layer 810 through the output node of the BEOL transistor. In this example, the output data 805 of the BEOL transistor of the logic layer 230 may be input to the adder tree of the adder layer 810 in the vertical direction through a via. The weight data 803 stored in the memory cell 215 may be input to, or output from, the BEOL transistor in the vertical direction through the via.

The 3D IMC device 800 may reduce latency due to data movement by reducing a moving path of data, compared to a planar 2D IMC device, by moving data between a plurality of layers through the vertical structure, such as 3D stacking.

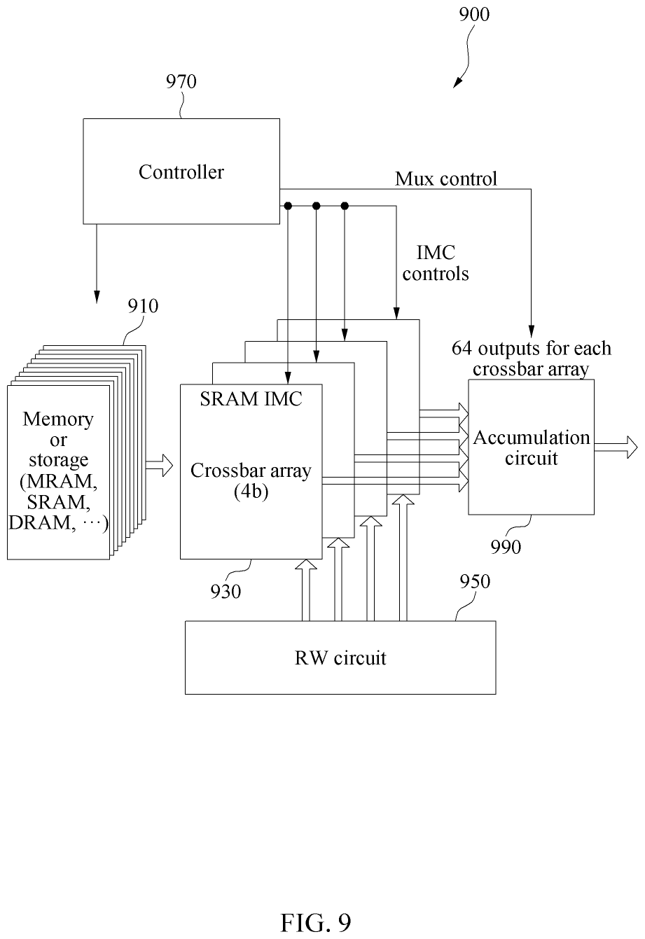

FIG. 9 illustrates an example of a computing device including a 3D IMC device according to one or more embodiments. Referring to FIG. 9, a neural computing device 900 according to an example may include a memory 910, an array circuit 920, a read write (RW) circuit 950, a controller 970, and an accumulation circuit 990, for example.

The memory 910 may store data applied to each of a plurality of 3D IMC devices 930 included in the array circuit 920. The data may be, for example, weight data or input data. The data may be, for example, stored in a form of a feature map or a vector matrix.

The array circuit 920 may include the plurality of 3D IMC devices 930. The plurality of 3D IMC devices 930 may be, for example, SRAM IMC macros, however the example is not limited thereto. In the plurality of 3D IMC devices 930, a memory array (e.g., the memory array 240 of FIG. 2B) including memory cells (e.g., the unit cells 220) may have a structure in which memory banks share one digital operator. The memory array may have, for example, a crossbar array structure, however the example is not limited thereto. The memory array may include a plurality of word lines, a plurality of bit lines intersecting with the plurality of word lines, and a plurality of memory cells (e.g., the unit cells 220) disposed at intersecting points between the plurality of word lines and the plurality of bit lines. The memory array may include, for example, 64 word lines and 64 bit lines. In this example, the size of the memory array may be expressed as 64×64. The word lines and the column lines in the memory array may be implemented by changing with each other. However, the example is not limited thereto.

Each of the memory cells may store data (e.g., weight data) applied by the memory 910. The memory cells may be non-volatile memory such as, for example, flash memory, magnetic random-access memory (MRAM), phase-change RAM (PRAM), and/or resistive RAM (RRAM). However, examples are not limited thereto.

The array circuit 920 may perform a MAC operation between weight data and input data stored in any one of the plurality of 3D IMC devices 930. In this example, the input data may be called from an input feature map stored in the memory 910, however the example is not limited thereto. For example, the MAC operation may be performed through an AND operation or a NAND operation by an arithmetic logic gate, however the example is not limited thereto.

For example, the array circuit 920 may correspond to the crossbar array 205 illustrated in FIG. 2B, however the example is not limited thereto.

The plurality of IMC devices 930 may express all data as digital logical values, such as “0” and/or “1”, to perform an operation. In addition, input data, weight data, and output data may have a binary format in the plurality of 3D IMC devices 930.

The 3D IMC device 930 may include an adder tree (e.g., the adder tree 245 of FIG. 2B) and a memory array (e.g., the memory array 240 of FIG. 2B) including a memory layer (e.g., the memory layer 210 of FIG. 2) and a logic layer (e.g., the logic layer 230 of FIG. 2). The 3D IMC device 930 may include one adder tree 245 corresponding to one memory array 240, as illustrated in FIG. 2B.

The memory layer may be implemented by an FEOL process and may include memory cells (e.g., the memory cells 215 of FIG. 2) configured to store first values (e.g., weight data). The memory cells may form the memory array. The logic layer may include arithmetic logic gates made up of transistors which are implemented by a BEOL process and vertically stacked on output ends of the memory cells. In this example, each of the arithmetic logic gates may be, in one example, a single BEOL transistor. The arithmetic logic gate may transmit an operation result corresponding to the memory cell to the adder tree.

Each of the transistors may operate as a multiplier and may transmit an operation result with a memory cell corresponding to each of the transistors to the adder tree (e.g., the adder tree 245 of FIG. 2B). Each of the transistors may share an input data line connected in the row direction in the logic layer through the gate terminal of the transistor, and an operation result between the first value and the second value applied through the input data line may be output for each column of the memory array including the memory cells.

As a non-limiting example, 64 first values (e.g., input data) may be applied to the 3D IMC device 930 for an operation for second values (e.g., weight data) of 64 bits stored in one word line of the memory array. Accordingly, 64-bit input data may be applied to the 3D IMC device 930 and an AND operation between the input data and the weight data stored in the memory array of the 3D IMC device 930 may be performed through a transistor. 64-bit AND operation results of the same word line may be summed through adder trees included in the 3D IMC device 930 and a final MAC operation result may be output through shift and accumulate operations for the summation result. The shift and accumulation operations may be performed by the accumulation circuit 990.

Each of the 3D IMC devices 930 may further include a second memory layer configured to store the second values input to the transistors in the vertical direction. The second memory layer may be connected to the gate terminal of the transistors by being vertically stacked on the upper end of the logic layer through the BEOL process. In this example, the first values and the second values stored in the memory cells may be input to the transistors in the vertical direction through a via formed in the logic layer.

Alternatively, each of the 3D IMC devices 930 may further include an adder layer in which an adder tree configured to perform an add operation for an operation result corresponding to each of the memory cells is formed. The adder layer may be vertically stacked on the upper end of the logic layer through a BEOL process. The adder tree may be 3D-stacked using a TSV method or a monolithic method and may be vertically connected to output nodes of the transistors. The 3D IMC device 930 may correspond to, for example, the 3D IMC device described with reference to FIGS. 2 to 8. However, the example is not limited thereto.

The RW circuit 950 may write data to the plurality of 3D IMC devices 930 or read data stored in the plurality of 3D IMC devices 930. The RW circuit 950 may read and write data of one or more memory cells included in each memory array of the plurality of 3D IMC devices 930. The data of the one or more memory cells may include, for example, input data values multiplied by weight data.

For example, the RW circuit 950 may access memory cells of a memory array through a bit line of the memory array of the plurality of 3D IMC devices 930. When a memory array includes a plurality of memory cells, the RW circuit 950 may access a memory cell connected to an activated word line of a plurality of word lines. The RW circuit 950 may write (or store) data to the accessed memory cell or may read data stored in the memory cell.

The controller 970 may generate and/or transmit control signals to operate each component (e.g., the memory 910, the 3D IMC device 930, the RW circuit 950, and the accumulation circuit 990) of the neural computing device 900 based on a clock signal.

Based on the clock signal, the controller 970 may input second values corresponding to an input signal of the neural computing device 900 to each of the plurality of 3D IMC devices 930 and may control the plurality of 3D IMC devices 930.

The accumulation circuit 990 may receive a summation operation of an adder tree for outputs of memory arrays of the plurality of 3D IMC devices 930 based on the control signal of the controller 970. The accumulation circuit 990 may perform shift and accumulation operations on the summation operation result and may output the result as a MAC operation result.

The accumulation circuit 990 may include a digital adder (e.g., an adder tree) configured to perform an add operation for an AND operation result corresponding to each of the memory cells of the memory array and a shift accumulator (not illustrated) configured to perform shift and accumulation operations for the add operation result of the digital adder.

The shift accumulator may perform shift and accumulation operations by receiving an output by the plurality of 3D IMC devices 930. The shift accumulator may perform a shift operation on partial sums corresponding to respective MAC operation results of the plurality of 3D IMC devices 930 and accumulate a result of the shift operation. For example, the shift accumulator may store the result of accumulation in a buffer and/or an output register. However, the example is not limited thereto. The shift accumulator may output a final MAC operation result by shifting bit positions corresponding to the same word line by a predetermined bit (e.g., one bit), applying the same to the summation result output from the corresponding word line, and accumulating the values of which bit positions are shifted.

The neural computing device 900 may be, or integrated into, for example, a mobile device, a mobile computing device, a mobile phone, a smartphone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, and a medical device, as non-limiting examples.

The neural computing device 900 may directly perform an operation in the memory in a state in which input data that changes every time is stored in the memory arrays of the plurality of 3D IMC devices 930 for inference, thereby reducing power consumption while greatly reducing the memory bandwidth as well. In addition, the neural computing device 900 may operate a larger network at the system level based on array circuit 920.

The neural computing device 900 may effectively operate various types of convolutional layers by controlling a shift operation by the structure in which the plurality of 3D IMC devices 930 share the shift accumulator.

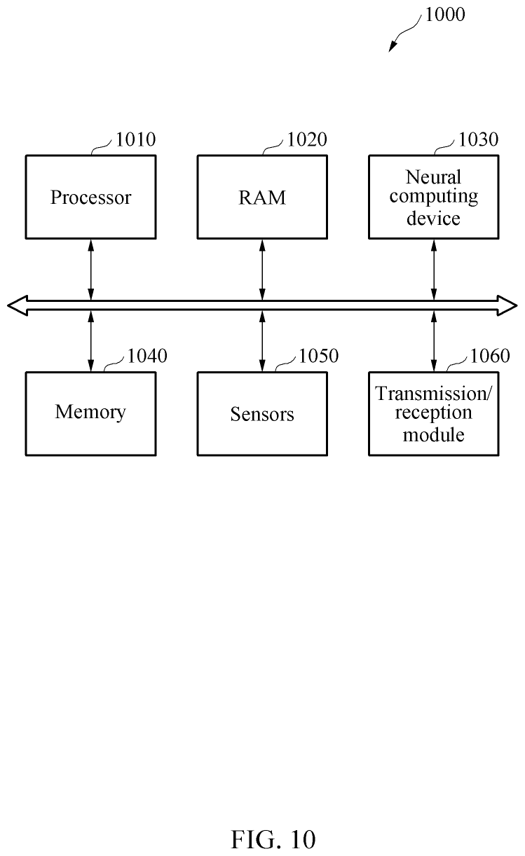

FIG. 10 illustrates an example of an electronic device or system. Referring to FIG. 10, an electronic system 1000 may infer information by analyzing input data in real time based on a neural network (e.g., the neural network 110 of FIG. 1) and determine a situation based on the information or control components of the electronic device 1000. For example, the electronic system 1000 may be a mobile device, a mobile computing device, a mobile phone, a smartphone, a personal digital assistant, a fixed location terminal, a tablet computer, a computer, a wearable device, a laptop computer, a server, a music player, a video player, an entertainment unit, a navigation device, a communication device, an IoT device, a GPS device, a television, a tuner, an automobile, an automotive part, an avionics system, a drone, a multi-copter, an eVTOL aircraft, and a medical device, as a non-limiting example.

The electronic system 1000 may include a processor 1010, random access memory (RAM) 1020, a neural computing device 1030, a memory 1040, sensors 1050, and a transmission/reception transceiver circuitry 1060. The electronic system 1000 may further include an input/output interface, security module 1080, power control circuitry 1090, and the like. A portion of hardware components of the electronic system 1000 may be included in at least one semiconductor chip.

The processor 1010 may control the overall operation of the electronic system 1000. The processor 1010 may include a single processor core (single core) or a plurality of processor cores (multi-core). The processor 1010 may be configured to execute (or process) instructions, programs, and/or data stored in the memory 1040. The processor 1010 may execute the instructions, which configures the processor 1010 to control operations or institution of the neural computing device 1030. The processor 1010 may be implemented as a central processing unit (CPU), a graphics processing unit (GPU), an application processor (AP), and the like.

The RAM 1020 may temporarily store programs, data, or instructions. For example, the programs, data, or instructions stored in the memory 1040 may be temporarily stored in the RAM 1020 according to control of the processor 1010 or booting code. The RAM 1020 may be implemented as a memory such as, for example, dynamic RAM (DRAM) or SRAM.

The neural computing device 1030 may perform inference (and/or training operations) on the neural network (e.g., the neural network 1010 of FIG. 10) based on received input data (or training data) and may generate various information based on a result of the operation. The neural network may include, for example, a convolutional neural network (CNN), a recurrent neural network (RNN), a fuzzy neural network (FNN), a deep belief network, a restricted Boltzmann machine, and the like. However, examples are not necessarily limited thereto. The neural computing device 1030 may be, for example, a hardware accelerator dedicated to the neural network and/or a device including the same. Here, in this context, the term “information” may include one of various types of recognition such as, for example, voice recognition information, object recognition information, video recognition information, and biological data recognition information.

The neural computing device 1030 may control SRAM memory cells of a 3D IMC device to share and/or process the same input data, and may select at least a portion of operation results output from the SRAM memory cells.

The neural computing device 1030 may be, for example, the neural computing device 900 of FIG. 9. However, the example is not limited thereto.

For example, the neural computing device 1030 may receive or store frame data included in a video stream as input data and may generate, from the frame data, recognition information for an object included in an image represented by the frame data. Alternatively, the neural computing device 1030 may receive various types of input data and generate recognition information according to the input data based according to various example electronic devices 1000 that may be different types and have different functions.

The memory 1040 is a storage configured to store data and may store an operating system (OS), various types of programs, and various types of data. Depending on examples, the memory 1040 may store intermediate results generated in a process of performing an inference (or training) operation of the neural computing device 1030. The intermediate results may also include intermediate MAC operation results (e.g., multiplier operations and accumulation operations)

The memory 1040 may include any one or any combination of a volatile memory and a non-volatile memory. The non-volatile memory may include, for example, read-only memory (ROM), programmable read-only memory (PROM), erasable programmable read-only memory (EPROM), electrically erasable programmable read-only memory (EEPROM), flash memory, magnetic RAM (MRAM), phase-change memory (PRAM), RRAM), and/or ferroelectric RAM (FRAM). However, examples are not necessarily limited thereto. The volatile memory may include, for example, DRAM, SRAM, SDRAM, and the like. However, examples are not necessarily limited thereto. Depending on an example, the memory 1040 may include any one or any combination of a hard disk drive (HDD), a solid state drive (SSD), a compact flash (CF) card, a secure digital (SD) card, a micro-SD card, a mini-SD card, an extreme digital (xD) picture card, and a memory stick, as non-limiting examples.

The sensors 1050 may collect information around (e.g., exterior to) the electronic system 1000. The sensors 1050 may sense or receive information (e.g., image information, audio information, magnetic information, biosignal data, touch information, etc.) from the outside of the electronic system 1000. The sensors may also convert the sensed or received information into a data form predetermined for use with one or more neural networks. The sensors 1050 may include at least one of various types of sensors such as, for example, a microphone, an imaging device, an image sensor, a light detection and ranging (LIDAR) sensor, an ultrasonic sensor, an infrared sensor, a biosensor, and a touch sensor, as a non-limiting example.

The sensors 1050 may provide the converted data to the neural computing device 1030 as input data, or the computer device 1030 may obtain or receive the same otherwise. For example, the sensors 1050 may include an image sensor and may generate a video stream by photographing an external environment of the electronic system and sequentially provide consecutive data frames of the video stream as input data to the neural computing device 1030. However, the example is not limited thereto, and the sensors 1050 may provide various types of data to the neural computing device 1030.

The transmission/reception transceiver circuitry 1060 may include various types of wired or wireless interfaces capable of communicating with an external apparatus. For example, the transmission/reception module 1060 may include a wired local area network (LAN), a wireless local area network (WLAN) such as wireless fidelity (Wi-Fi), a wireless personal area network (WPAN) such as Bluetooth, a wireless universal serial bus (USB), ZigBee, near field communication (NFC), radio-frequency identification (RFID), power line communication (PLC), a communication interface accessible to a mobile cellular network, such as 3rd Generation (3G), 4th Generation (4G), and Long Term Evolution (LTE), and the like.

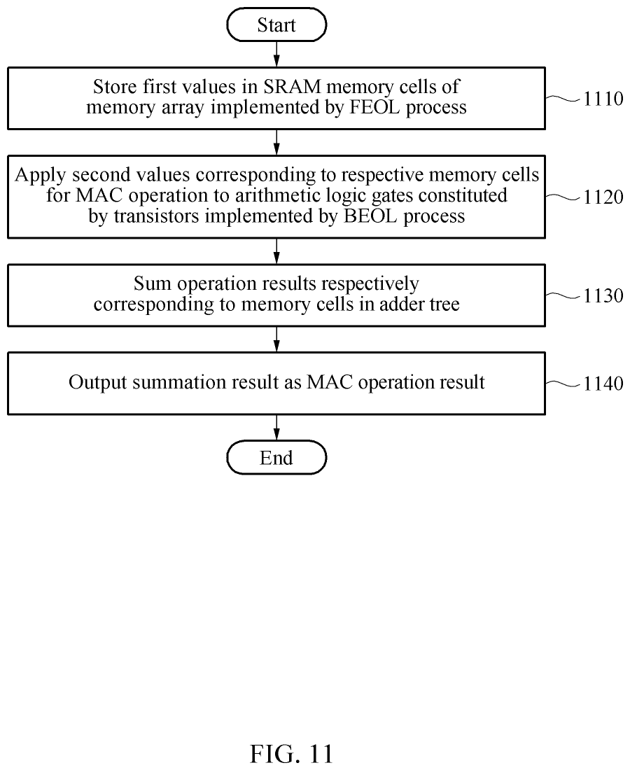

FIG. 11 illustrates an example of an operating method of a 3D IMC device according to one or more embodiments. In the following examples, operations may be performed sequentially, but not necessarily performed sequentially. For example, the order of the operations may change, and at least two of the operations may be performed in parallel.

Referring to FIG. 11, a 3D IMC device according to an example may transmit a MAC operation result to an adder tree and add the MAC operation result through operations 1110 to 1140.

In operation 1110, the 3D IMC device may store first values in SRAM memory cells of a memory array implemented by an FEOL process.

In operation 1120, the 3D IMC device may apply second values corresponding to respective memory cells for a MAC operation to arithmetic logic gates including transistors implemented by a BEOL process.

In operation 1130, the 3D IMC device may sum operation results respectively corresponding to the memory cells in the adder tree.

In operation 1140, the 3D IMC device may output the summation result of operation 1130 as a MAC operation result.

The controller 960, RW circuit 950, accumulation circuit 990, processor 1010, RAM 1020, neural computing device 1030, memory 1040, sensors 1050, and transmission/reception module 1060 in FIGS. 1-10 that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-10 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An apparatus, comprising:
a memory layer comprising a plurality of front-end-of-line (FEOL) memory cells; and
a logic layer comprising plural arithmetic logic gates comprising a plurality of back-end-of-line (BEOL) transistors, the plurality of BEOL transistors being vertically stacked on respective upper ends of the plurality of memory cells, wherein each of multiple transistors of the plurality of BEOL transistors operates as a multiplier and is configured to provide an operation result with respect to first values stored in corresponding memory cells of the plurality of memory cells.

2. The apparatus of claim 1, wherein the multiple transistors are configured to share an input data line connected in a row direction in the logic layer through respective gate terminals of the multiple transistors, and
wherein the multiplier operation results are multiplier results between the first values and a second value applied through the input data line, and are output for each column of a memory array comprising multiple memory cells of the plurality of memory cells.

3. The apparatus of claim 2, wherein a total number of the multiple transistors is equal to a total number of the plurality of memory cells, and
wherein a total number of the multiple memory cells is equal to a total number of the plurality of memory cells.

4. The apparatus of claim 1, wherein the plural arithmetic logic gates are vertically stacked to respectively correspond to the plurality of memory cells.

5. The apparatus of claim 1, wherein the plurality of BEOL transistors each comprise a negatively doped metal-oxide semiconductor (n-MOS) transistor,
wherein a source terminal of the n-MOS transistor is grounded through a resistor,
wherein a gate terminal of the n-MOS transistor is connected to an input data line,
wherein a drain terminal of the n-MOS transistor is connected to a memory cell corresponding to an arithmetic logic gate of the plurality of memory cells, and
wherein the operation result is output through an output node disposed between the source terminal of the n-MOS transistor and the resistor.

6. The 3D IMC device of claim 1, wherein the plurality of BEOL transistors each comprise a positively doped metal-oxide semiconductor (p-MOS) transistor,
wherein a gate terminal of the p-MOS transistor is connected to an input data line,
wherein a drain terminal of the p-MOS transistor is connected to a memory cell corresponding to an arithmetic logic gate of the plurality of memory cells,
wherein a source terminal of the p-MOS transistor is connected to a voltage source (VDD) through a resistor, and
wherein the operation result is output through an output node disposed between the source terminal of the p-MOS transistor and the resistor.

7. The 3D IMC device of claim 1, wherein the plurality of BEOL transistors comprise any one or any combination of two or more of a thin film transistor (TFT), a ferroelectric field-effect transistor (FeFET), a two-dimensional (2D) field effect transistor (FET), and a polycrystalline silicon (poly-Si) channel FET.

8. The apparatus of claim 1, wherein the logic layer includes a plurality of logic layer memory cells,
wherein a unit cell represents a collection of one memory cell of the plurality of logic layer memory cells, and one arithmetic logic gate of the plurality of arithmetic logic gates, corresponding to the one memory cell, and
wherein multiple unit cells, of the plurality of unit cells represent a memory array configured to perform a matrix operation sharing a data line of the corresponding memory cells.

9. The apparatus of claim 8, further comprising one or more static random access memory (SRAM) crossbar arrays, wherein the unit cell corresponds to one bit cell of one of the SRAM crossbar arrays.

10. The apparatus of claim 8, wherein the memory layer comprises:
a plurality of word lines;
a plurality of bit lines intersecting with the plurality of word lines; and
the corresponding memory cells being disposed at intersecting points between the plurality of word lines and the plurality of bit lines.

11. The apparatus of claim 1, wherein the logic layer comprises a metal layer and plural with multiple vias of the plurality of vias being disposed to interconnect the multiple transistors to the first values stored in the corresponding memory cells.

12. The apparatus of claim 1, further comprising a second memory layer,
wherein the second memory layer is vertically stacked on an upper end of the logic layer connected to a respective gate terminal of the plurality of transistors, and
wherein the second memory layer is vertically stacked by a back-end-of-line (BEOL) process, and 3-D stacked by one of a through silicon via (TSV) method or a monolithic method.

13. The apparatus of claim 1, further comprising a second memory layer,
wherein the second memory layer is vertically stacked on an upper end of the logic layer connected to a respective gate terminal of the plurality of transistors,
wherein the second memory layer includes a plurality of second layer memory cells,
wherein multiple second layer memory cells of the plurality of second layer cells respectively store second values, and
wherein the respective multiplier operations of the multiple transistors are performed with respect to the first values and the second values input to the multiple transistors in the vertical direction through respective vias formed in the logic layer.

14. The apparatus of claim 1, further comprising:
an adder layer including an adder tree configured to perform an add operation with respect to the multiplier operation results,
wherein the adder layer is vertically stacked on an upper end of the logic layer.

15. The apparatus of claim 14, wherein the adder layer is vertically stacked by a back-end-of-line (BEOL) process,
wherein the adder tree is 3D-stacked by one of a through silicon via (TSV) method or a monolithic method, and
wherein the adder tree is connected to an output node of respective ones of the multiple transistors in a vertical direction.

16. The apparatus of claim 1, wherein the apparatus is an electronic device, and is a mobile device, a mobile computing device, a mobile phone, a smartphone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, or a medical device.

17. An electronic device, comprising:
an array circuit comprising a plurality of the 3D IMC devices; and
a controller configured to implement a neural network through a provision of input second values to each of the plurality of 3D IMC devices and control of the plurality of 3D IMC devices,
wherein each of the 3D IMC devices comprises:
a memory layer comprising a plurality of front-end-of-line (FEOL) memory cells; and
a logic layer comprising plural arithmetic logic gates comprising a plurality of back-end-of-line (BEOL) transistors, the plurality of BEOL transistors being vertically stacked on respective output ends of the plurality of memory cells, wherein each of plural transistors of the plurality of BEOL transistors operates as a multiplier and is configured to provide an operation result with respect to first values stored in corresponding memory cells of the plurality of memory cells.

18. The device of claim 17, further comprising:
a second memory layer,
wherein the second memory layer is vertically stacked on an upper end of the logic layer connected to a respective gate terminal of the plurality of transistors,
wherein the second memory layer is vertically stacked a back-end-of-line (BEOL) process, and
wherein the first values and the second values are input to the plural transistors in the vertical direction through respective vias formed in the logic layer.

19. The device of claim 17, further comprising:
an adder layer including an adder tree configured to perform an add operation with respect to the multiplier operation results,
wherein the adder layer is vertically stacked by a back-end-of-line (BEOL) process,
wherein the adder tree is 3D-stacked by one of a through silicon via (TSV) method or a monolithic method, and
wherein the adder tree is connected to an output node of respective ones of the plural transistors in the vertical direction.

20. A method, the method comprising:
storing first values in static read-only access memory (SRAM) cells of a front-end-of-line (FEOL) memory array;
applying second values respectively corresponding to memory cells for a multiplication and accumulation (MAC) operation to arithmetic logic gates comprising back-end-of-line (BEOL) transistors;
transmitting and summing operation results respectively corresponding to the memory cells; and
outputting a result of a summation from the summing.
